(19) United States
(12) Patent Application Publication
(10) Pub. No.: US 2014/0357077 A1
(43) Pub. Date: Dec. 4, 2014

(54) METHODS FOR FABRICATING SEMICONDUCTOR DEVICES HAVING THROUGH ELECTRODES

(71) Applicant: Samsung Electronics Co., Ltd., Suwon-si (KR)

(72) Inventors: SOYOUNG LEE, Suwon-si (KR); JIN HO AN, Seoul (KR); Byung Lyul PARK, Seoul (KR); JISOON PARK, Suwon-si (KR)

(73) Assignee: Samsung Electronics Co., Ltd., Suwon-si (KR)

(21) Appl. No.: 14/190,090

(22) Filed: Feb. 25, 2014

(30) Foreign Application Priority Data
May 29, 2013 (KR) 10-2013-0061205

(51) Int. Cl. H01L 21/768

(52) U.S. Cl. CPC H01L 21/76802
USPC 438/667

(57) ABSTRACT

Provided are methods for fabricating semiconductor devices having through electrodes. The method may comprise forming a polishing stop layer having a multi-layered structure on a substrate, forming a via hole partially penetrating the substrate, providing the substrate with a first cleaning solution to first clean the substrate, providing the substrate with a second cleaning solution to second clean the substrate, the second cleaning solution being different from the first cleaning solution, and forming a through electrode in the via hole.

### CROSS-REFERENCE TO RELATED APPLICATIONS

This U.S. nonprovisional patent application claims priority under 35 U.S.C. §119 of Korean Patent Application 10-2013-0061205 filed on May 29, 2013, the entire contents of which are hereby incorporated by reference.

### BACKGROUND

The present inventive concept relates to semiconductors and, more particularly, to methods for fabricating semiconductor device having through electrodes.

Through electrodes or TSVs are proposed to electrically connect semiconductor devices to other semiconductor devices or printed circuit boards. The through electrodes can be used to accomplish 3-dimensional structures and fast transfer rate compared to solder balls or solder bumps. To form the through electrode, a polishing stop layer is generally formed on a substrate and a hole is formed for the through electrode.\ There are needed to secure the thickness uniformity of the polishing stop layer to prevent the inferiority of polishing process and electrical malfunctions.

### SUMMARY

Embodiments of the present inventive concept provide methods for fabricating semiconductor devices having through electrodes in which thickness uniformities of polishing stop layers.

Embodiments of the present inventive concepts provide methods for fabricating semiconductor devices having through electrodes capable of minimizing or reducing process inferiority for through electrode.

According to exemplary embodiments of the present inventive concepts, a method for fabricating a semiconductor device may comprise: forming a polishing stop layer having a multi-layered structure on a substrate; forming a via hole partially penetrating the substrate; providing the substrate with a first cleaning solution to first clean the substrate; providing the substrate with a second cleaning solution to second clean the substrate, the second cleaning solution being different from the first cleaning solution; and forming a through electrode in the via hole.

In some embodiments, forming the polishing stop layer may comprise: forming a first insulating layer on the substrate; and forming a second insulating layer on the first insulating layer, the second insulating layer including an insulator different from that of the first insulating layer.

In some embodiments, the first insulating layer may comprise a silicon nitride layer and the second insulating layer may comprise a silicon oxide layer.

In some embodiments, forming the polishing stop layer may comprise: forming a first insulating layer on the substrate; and forming a second insulating layer on the first insulating layer, the second insulating layer including an insulator identical to that of the first insulating layer. A component content of the second insulating layer may be different from that of the first insulating layer.

In some embodiments, the first and second insulating layers comprise a silicon nitride layer. The second insulating layer may have hydrogen content lower than that of the first insulating layer.

In some embodiments, forming the via hole may comprise: forming an organic mask on the polishing stop layer; and patterning the substrate using the organic mask to form the via hole whose top end is opened to a top surface of the substrate and whose bottom end is not reached a bottom surface of the substrate.

In some embodiments, the first cleaning solution may comprise sulfuric acid and hydrogen peroxide.

In some embodiments, second cleaning may comprise providing the substrate with the second cleaning solution including hydrogen fluoride.

In some embodiments, forming the through electrode may comprise: forming a via insulating layer extending along an inner surface of the via hole; forming a conductive layer filling the via hole on the substrate; and polishing the conducive layer to form the through electrode that fills the via hole and is electrically insulated from the substrate by the via insulating layer.

In some embodiments, after polishing the conductive layer, the method may further comprise removing the polishing stop layer.

According to exemplary embodiments of the present inventive concepts, a method for fabricating a semiconductor device may comprise: forming a polishing stop layer on a substrate; forming an oxidation preventing layer covering the polishing stop layer; forming a via hole partially penetrating the substrate; providing the substrate with a first cleaning solution including sulfuric acid and hydrogen peroxide to first clean the substrate; providing the substrate with a second cleaning solution including hydrogen fluoride to second clean the substrate; forming a via insulating layer extending along an inner surface of the via hole; forming a conductive layer filling the via hole on the substrate; polishing the conductive layer until the polishing stop layer is exposed so as to form a through electrode; and removing the polishing stop layer. The oxidation preventing layer may prevent the polishing layer from contacting the first cleaning solution such that the polishing stop layer may be prevented from oxidizing.

In some embodiments, the polishing stop layer may comprise a silicon nitride layer and the oxidation preventing layer may comprise a silicon oxide layer.

In some embodiments, forming the via hole may comprise: coating and patterning a photoresist on the oxidation preventing layer to form a mask; and performing an etching using the mask to remove a portion of the substrate. The via hole may be opened to a top surface of the substrate and not reached a bottom surface of the substrate.

In some embodiments, after forming the via hole, the method may further comprise removing the mask, wherein first cleaning the substrate may comprise removing a remainder of the mask.

In some embodiments, second cleaning the substrate may comprise removing the oxidation preventing layer.

### BRIEF DESCRIPTION OF THE DRAWINGS

The foregoing and other features and advantages of exemplary embodiments of inventive concepts will be apparent from the more particular description of non-limiting embodiments of inventive concepts, as illustrated in the accompanying drawings in which like reference characters refer to the same parts throughout the different views. The drawings are not necessarily to scale, emphasis instead being placed upon illustrating the principles of inventive concepts. In the drawings:

FIG. 1A is a cross sectional view illustrating a semiconductor device according to exemplary embodiments of the present inventive concepts;

FIG. 1B is a cross sectional view illustrating a semiconductor package in which the semiconductor device of FIG. 1A is packaged;

FIGS. 2A to 2K are cross sectional view illustrating a method for fabricating a semiconductor device according to exemplary embodiments of the present inventive concepts;

FIGS. 3A and 3B are cross sectional views for comparing a method of an embodiment with a method different therefrom;

FIGS. 4A to 4C are cross sectional views illustrating modified embodiments of FIG. 2K;

FIG. 5A is a schematic block diagram illustrating an example of memory cards including a semiconductor apparatus according to exemplary embodiments of the present inventive concepts; and

FIG. 5B is a schematic block diagram illustrating an example of information process system including a semiconductor apparatus according to exemplary embodiments of the present inventive concepts.

### DETAILED DESCRIPTION OF PREFERRED EMBODIMENTS

Example embodiments of inventive concepts will now be described more fully hereinafter with reference to the accompanying drawings, in which some example embodiments of inventive concepts are shown. Example embodiments, may, however, be embodied in many different forms and should not be construed as being limited to the embodiments set forth herein; rather, these example embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements. Hereinafter, it will be described about an exemplary embodiment of the present invention in conjunction with the accompanying drawings.

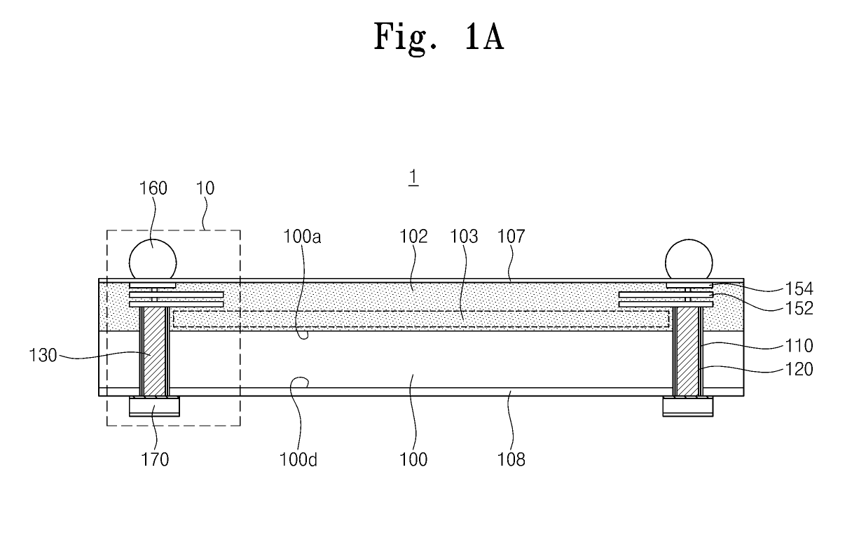

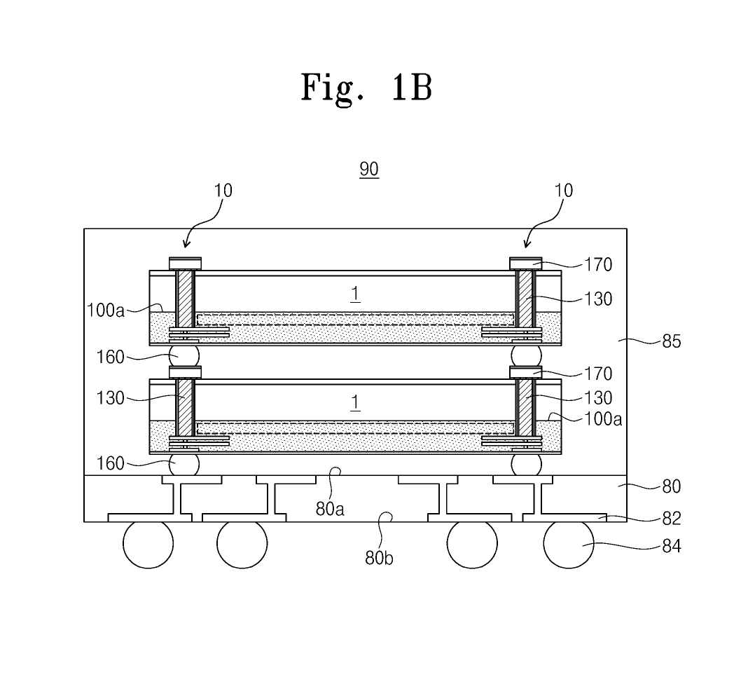

FIG. 1A is a cross sectional view illustrating a semiconductor device according to exemplary embodiments of the present inventive concepts.

Referring to FIG. 1A, a semiconductor device 1 may comprise an electrical interconnection 10 which is configured to transmit an electrical signal vertically passing through a substrate 100. The electrical interconnection 10 may comprise a through electrode 130 substantially vertically penetrating the substrate 100. A via insulating layer 110 may be provided between the through electrode 130 and the substrate 100 such that the through electrode 130 may be electrically insulated from the substrate 100. A barrier layer 120 may be further provided between the through electrode 130 and the substrate 100 to prevent a component (e.g., copper) of the through electrode 130 from diffusing into the substrate 100.

The semiconductor device 1 may further comprise at least one of an upper terminal 160 and a lower terminal 170 which are electrically connected to the through electrode 130. The upper terminal 160 may be disposed on an active surface 100a of the substrate 100 and the lower terminal 170 may be disposed on an inactive surface 100d of the substrate 100. At least one of the upper and lower terminals 160 and 170 may comprise a solder ball, a solder bump, a redistributed line, a pad, and so forth. For example, the upper terminal 160 may comprise a solder ball and the lower terminal 170 may comprise a pad.

An integrated circuit 103, a metal line 152 and an interlayer insulating layer 102 may be disposed on the active surface 100a of the substrate 100. The metal line 152 may be electrically connected to the integrated circuit 103 and have a single-layered or multi-layered structure. The interlayer insulating layer 102 may cover the integrated circuit 103 and the metal line 152. An upper insulating layer 107 may be disposed on the interlayer insulating layer 102 and expose a bonding pad 154 electrically connected to the upper terminal 160. The metal line 152 and the through electrode 130 may be electrically connected to each other, thereby electrically connecting the through electrode 130 to the integrated circuit 103. The through electrode 130 may locate around or in the integrated circuit 103. A lower insulating layer 108 may be disposed on the inactive surface 100d of the substrate 100. The electrical interconnection 10 may have various structures as will be described later.

FIG. 1B is a cross sectional view illustrating a semiconductor package in which the semiconductor device of FIG. 1A is packaged.

Referring to FIG. 1B, a semiconductor package 90 may comprise a package substrate 80 and one or more semiconductor devices 1 of FIG. 1A mounted on the package substrate 80. The semiconductor package 90 may further comprise a mold layer 85 encapsulating the semiconductor devices 1. The package substrate 80 may include a top surface 80a and a bottom surface 80b facing each other and, in example embodiments, it may be a printed circuit board provided with electrical connection lines 82. The semiconductor devices 1 may be mounted on the top surface 80a of the package substrate 80, for example, in a face-down manner, such that the active surfaces 100a may face the package substrate 80. Alternatively, the semiconductor devices 1 may be mounted on the top surface 80a of the package substrate 80 in a face-up manner such that the active surfaces 100a may face upward. The semiconductor package 90 may further comprise one or more solder balls 84 attached to the bottom surface 80b of the package substrate 80 and coupled to the electrical connection lines 82. In some embodiments, the through electrodes 130 may allow electrical connections between the semiconductor devices 1 and between the semiconductor devices 1 and the package substrate 80. The electrical interconnections 10 of the semiconductor devices 1 may comprise at least one of electrical interconnections 11, 12, 13 and 14 described later.

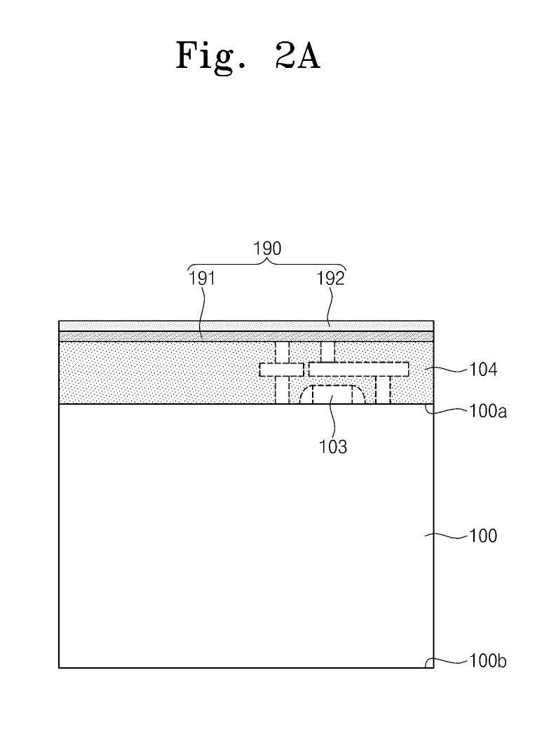

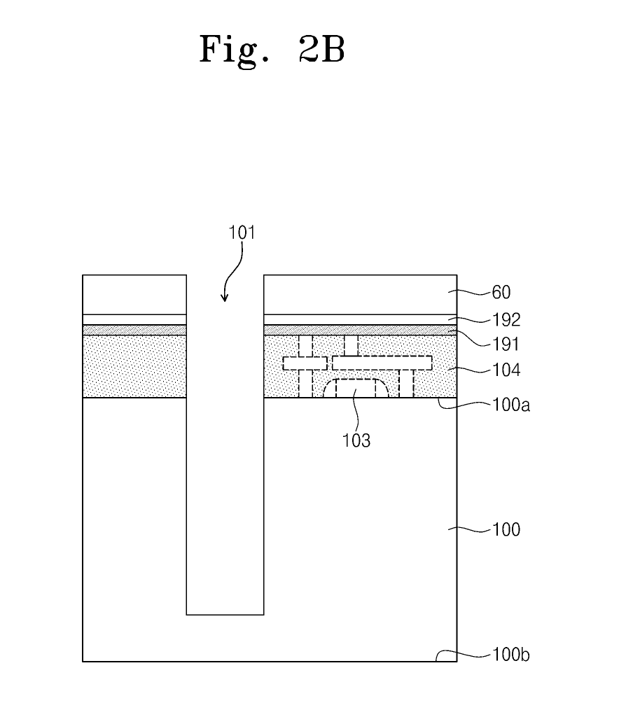

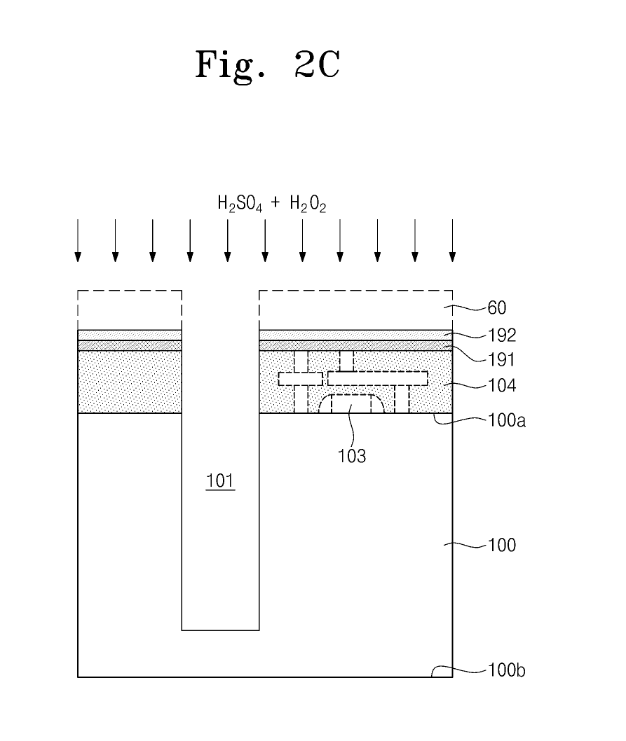

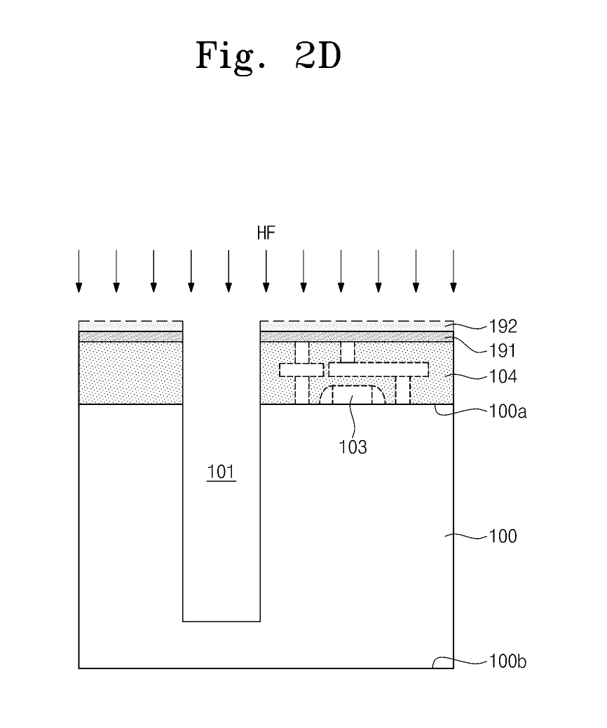

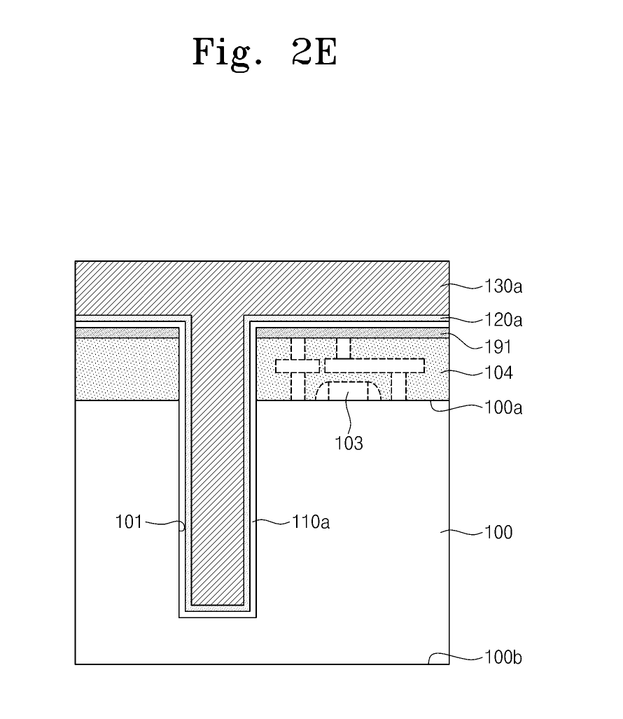

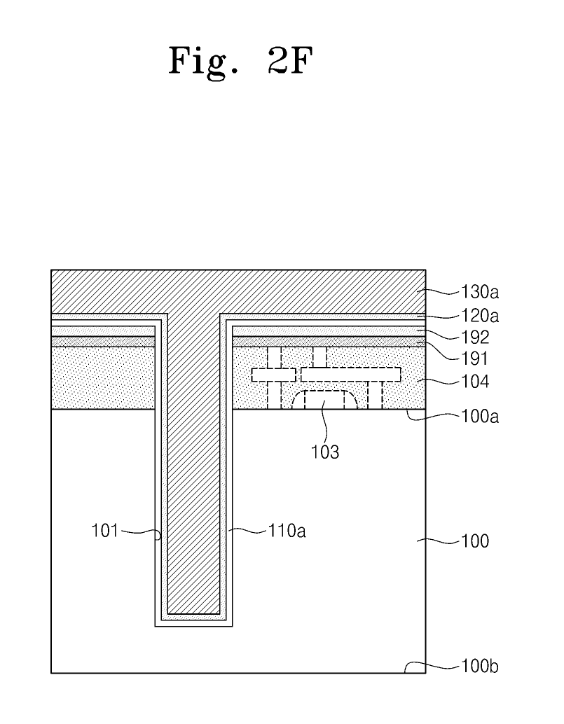

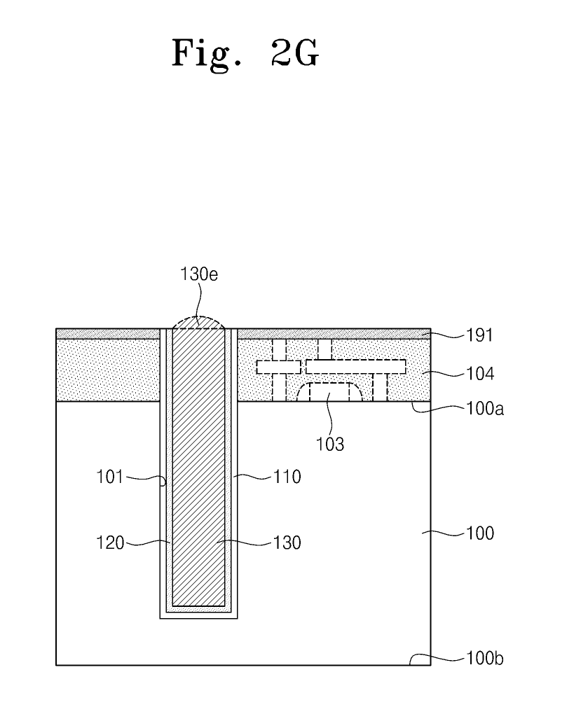

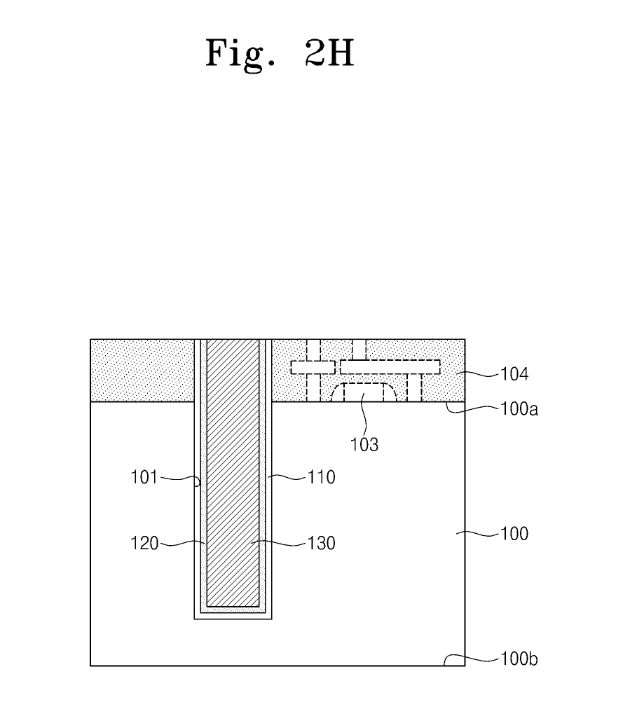

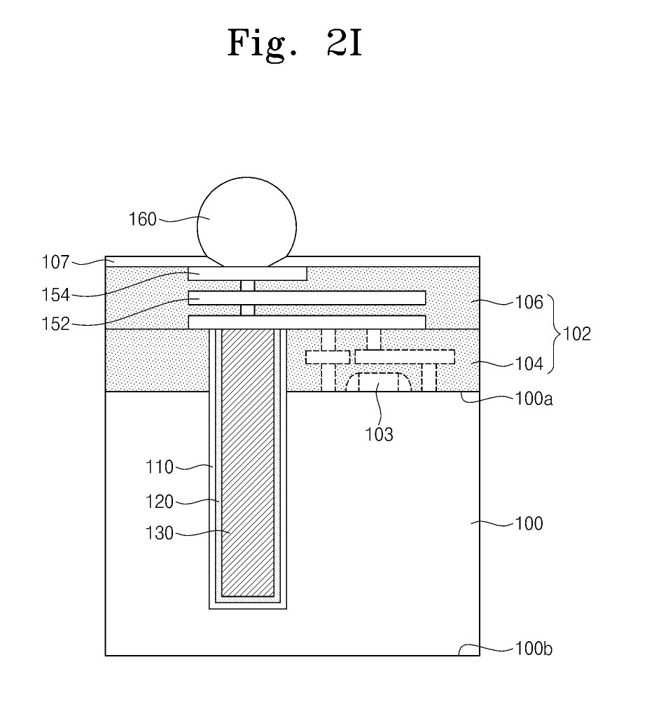

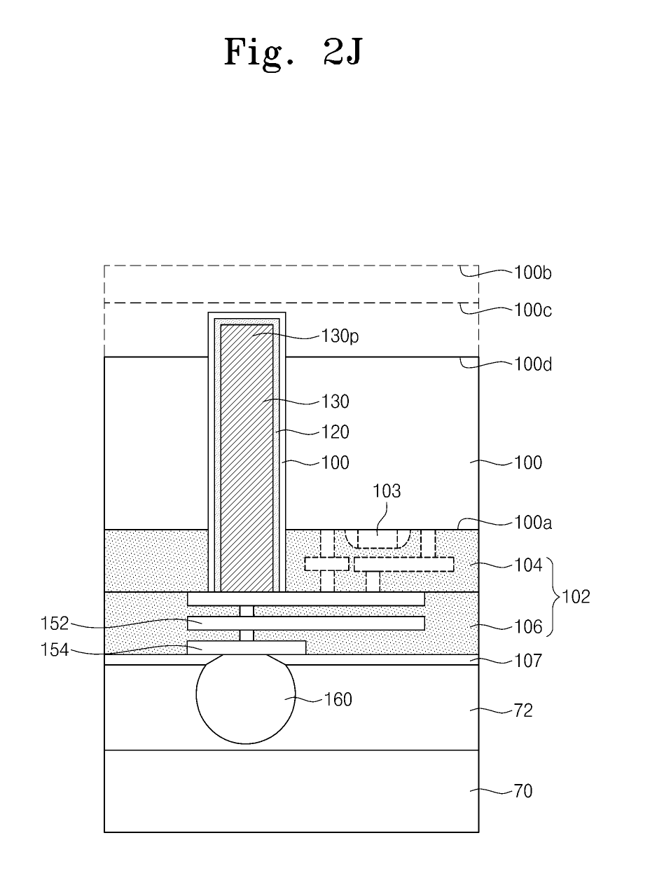

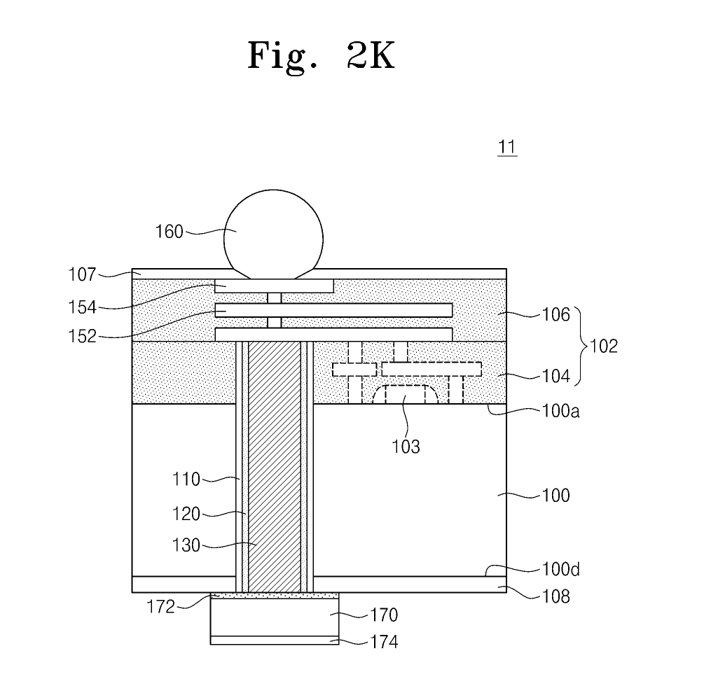

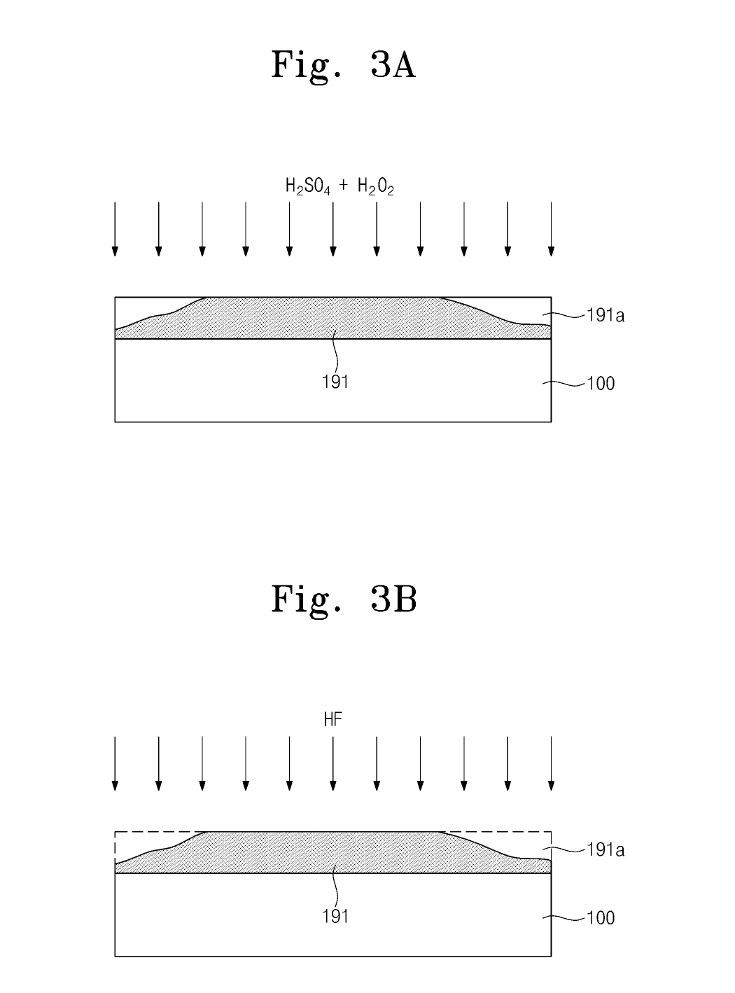

FIGS. 2A to 2K are cross sectional view illustrating a method for fabricating a semiconductor device according to exemplary embodiments of the present inventive concepts. FIGS. 3A and 3B are cross sectional views for comparing a method of an embodiment with a method different therefrom.

Referring to FIG. 2A, a polishing stop layer 190 may be formed on the substrate 100. The substrate 100 may be a semiconductor substrate (for example, a wafer-level or chip-level silicon substrate) having a top surface 100a and a first bottom surface 100b opposite the top surface 100a. A first interlayer insulating layer 104 may be formed on the top surface 100a to cover the integrated circuit 103. The integrated circuit 103 may comprise a memory circuit, a logic circuit or a combination thereof. The first interlayer insulating layer 104 may be formed by depositing a silicon oxide layer or a silicon nitride layer.

The polishing stop layer 190 may protect the top surface 100a of the substrate 100 and/or the integrated circuit 103 in a polishing process (e.g., CMP) described later with reference to FIG. 2G. The polishing stop layer 190 may be a multi-layered structure comprising a first polishing stop layer 191 and a second polishing stop layer 192. The first polishing stop layer 191 may be formed on the first interlayer insulating layer 104 to cover the integrated circuit 103, and the second polishing stop layer 192 may be formed on the first polishing stop layer 191 to cover the first polishing stop layer 191. The first polishing stop layer 191 may substantially act as a stop point of a polishing process, as described later with reference to FIG. 2G, and the second polishing stop layer 192 may act as a passivation layer which prevents an oxidation of the first polishing stop layer 191, as described later with reference to FIG. 2D. Furthermore, the second polishing stop layer 192 may suppress a non-uniform oxidation of the first polishing stop layer 192 in a cleaning process, as described later with reference to FIG. 2D.

In some embodiments, the first polishing stop layer 191 and the second polishing stop layer 192 may be formed of different insulating materials. For example, the first polishing stop layer 191 may be formed by depositing a silicon nitride layer (e.g., SiN), and the second polishing stop layer 192 may be formed by depositing a silicon oxide layer (e.g., SiO₂, HARP oxide). The silicon nitride layer constituting the first polishing stop layer 191 may comprise hydrogen. For example, when the first polishing stop layer 191 is formed by a chemical vapor deposition (e.g., PECVD) process using a gas including SiH₄/NH₃/H₂, hydrogen may be included in the silicon nitride layer.

Alternatively, the first polishing stop layer 191 and the second polishing stop layer 192 may be formed of same insulating materials whose physical or chemical characteristics are different from each other. For example, the first polishing stop layer 191 and the second polishing stop layer 192 may be formed of a silicon nitride layer, and the second polishing stop layer 192 may include a hydrogen content different from that of the first polishing stop layer 191. In some embodiments, the second polishing stop layer 192 may include a low hydrogen content compared to the first polishing stop layer 191.

The difference of hydrogen content may allow the second polishing stop layer 192 to have a CMP removal rate different from that of the first polishing stop layer 191. For example, the second polishing stop layer 192 may have a lower hydrogen content and a lower CMP removal rate compared to the first polishing stop layer 191.

It may be needed that the first polishing stop layer 191 has an ability to withstand a chemical mechanical polishing. Therefore, it may be preferable that the first polishing stop layer 191 is formed by depositing a silicon nitride layer having a low hydrogen content and a low CMP removal rate, such that the first polishing stop layer 191 may have a uniform thickness even after the chemical mechanical polishing process is performed. For depositing a silicon nitride layer having a low hydrogen content, high frequency RF power may be so high that the integrated circuit 103 may be damaged, thereby fluctuating a threshold voltage of the integrated circuit 103. To avoid the inferiority of the integrated circuit 103, the first polishing stop layer 191 may be formed by depositing a silicon nitride layer having a high hydrogen content under a condition that the high frequency RF power is decreased. The first polishing stop layer 191 having a high hydrogen content may have a non-uniform thickness after the chemical mechanical polishing process and a high CMP removal rate. Furthermore, a non-uniform oxidation may occur to the first polishing stop layer 191 having a high hydrogen content.

According to some embodiments, the first polishing stop layer 191 may be formed by depositing a silicon nitride layer having a high hydrogen content so as to avoid the inferiority of the integrated circuit 103, and the second polishing stop layer 192 may be formed by depositing a silicon nitride layer having a low hydrogen content or a silicon oxide layer so as to secure a thickness uniformity of the first polishing stop layer 191 and prevent a non-uniform oxidation of the first polishing stop layer 191.

Referring to FIG. 2B, a via hole 101 may be formed in the substrate 100. The via hole 101 may be formed to have a hollow pillar shape having an entrance near the top surface 100a of the substrate 100 but having a such a depth as not to penetrate the first bottom surface 100b. The via hole 101 may extend from the top surface 100a toward the first bottom surface 100b in a substantially vertical direction. The via hole 101 may be formed around the integrated circuit 103 (for example, a scribe lane or a region adjacent to thereto) or at a region provided with the integrated circuit 103. For example, a mask 60 may be formed by coating and patterning photoresist on the second polishing stop layer 192, and the via hole 101 may be formed by a dry etching process using the mask 60.

Referring to FIG. 2C, the mask 60 may be removed by an ashing process. After the ashing process, a first cleaning process may be further performed to remove residues of the mask 60. The first cleaning process may use a cleaning solution capable of removing an organic material (e.g., photoresist) which is used to form the mask 60. For example, the first cleaning process using a diluted sulfuric peroxide (DSP), which is a mixture of sulfuric acid (H₂SO₄) and hydrogen peroxide (H₂O₂), may be performed to remove the organic material, as described by the following reaction formula 1.

H₂SO₄+H₂O₂+organic material (PR)→CO₂+H₂O+NO₂+SO₂ [Reaction Formula 1]

The first cleaning process, also known as Piranha or DSP cleaning process, may be performed while rotating the substrate 100.

According to some embodiments, the second polishing stop layer 192 may suppress a reaction of the first polishing stop layer 191 and the DSP cleaning solution such that the first polishing stop layer 191 may be prevented from oxidizing, which will be described in detail with reference to FIG. 2D.

Referring to FIG. 2D, a second cleaning process may be performed. The second cleaning process may clean the substrate 100 to improve a wetting condition in a successive process. The second cleaning process may use hydrogen fluoride (HF) as a cleaning solution. This HF cleaning process may partially or wholly remove the second polishing stop layer 192 formed of a silicon oxide (e.g., SiO₂). Alternatively, the second polishing stop layer 192 formed of a silicon nitride (e.g., SiN) may remain when the HF cleaning is performed.

When the second polishing stop layer 192 is not formed, SiN constituting the first polishing stop layer 191 may react with hydrogen peroxide (H₂O₂) to create SiNxOy in the DSP cleaning process, as described by the following reaction formula 2. In other words, the first polishing stop layer 191 may be partially oxidized. When the first polishing stop layer 191 is formed by depositing silicon nitride having a high content of hydrogen, the oxidized portion may be greater.

SiN+H₂O₂→H₂O+H₂+SiNxOy [Reaction Formula 2]

The oxidized portion (SiNxOy) of the first polishing stop layer 191 may react with hydrogen peroxide (H₂O₂) and be removed in the HF cleaning process described in reaction formulas 3 and 4.

SiNxOy+zHF→aSiF₄+bH₂O+cN₂ [Reaction Formula 3]

SiF₄+2HF→CO₂+H₂SiF₆ [Reaction Formula 4]

According to reaction formulas 3 and 4, SiNxOy may react with HF to create H₂SiF₆ so that the first polishing stop layer 191 may be partially removed.

As described above, if the second polishing stop layer 192 is not formed, the first polishing stop layer 191 may be partially oxidized in the DSP cleaning process, as illustrated in FIG. 3A, and the oxidized portion 191a may be removed in the HF cleaning process, as illustrated in FIG. 3B. Consequently, the first polishing stop layer 191 may have poor uniformity such as uneven thickness. Especially, when the DSP cleaning process is performed while rotating the substrate 100, the oxidized portion 191a may be concentrated on edges of the substrate 100 such that the thickness uniformity of the first polishing stop layer 191 may become more serious. The poor thickness uniformity of the first polishing stop layer 191 may lead to its malfunction in a chemical polishing process, as described later with reference to FIG. 2G, thereby causing failure of polishing process and physical or electrical damages of the integrated circuit 103.

In some embodiments, the second polishing stop layer 192 may prevent the first polishing stop layer 191 from reacting with the DSP such that oxidation of the first polishing stop layer 191 and the poor thickness uniformity thereof may be eliminated or reduced.

Referring to FIG. 2E, an insulating layer 110a may be formed to extend along an inner surface of the via hole 101 and a conductive layer 130a may be formed on the substrate 100 so as to fill the via hole 101. The insulating layer 110a may be formed by depositing a silicon oxide layer or a silicon nitride layer. The conductive layer 130a may be formed by depositing or plating polysilicon, copper, tungsten, aluminum, and so forth. When the conductive layer 130a is formed of copper or conductive material comprising copper, a metal layer 120a capable of preventing diffusion of copper may be further formed on the conductive layer 110a. The metal layer 120a may be formed to extend along the insulating layer 110a by depositing metal comprising titanium (Ti), titanium nitride (TiN), chrome (Cr), tantalum (Ta), tantalum nitride (TaN), nickel (Ni), tungsten (W), tungsten nitride (WN) or any combination thereof. Selectively, an annealing process may be further performed after the formation of the conductive layer 130a.

In some embodiments, when the second polishing stop layer 192 is formed of silicon oxide, the second polishing stop layer 192 may be removed in the HF cleaning process. Therefore, the first polishing stop layer 191 may remain between the conductive layer 130a and the top surface 100a of the substrate 100.

Alternatively, when the second polishing stop layer 192 is formed of silicon nitride, the second polishing stop layer 192 may not be removed in the HF cleaning process. In this case, as illustrated in FIG. 2F, the first polishing stop layer 191 may be covered with the second polishing stop layer 192.

Referring to FIG. 2G, the conductive layer 130a may be planarized. For example, a chemical polishing process may be performed on the conductive layer 130a until the first polishing stop layer 191 is exposed. Due to the polishing process, the conductive layer 130a may be formed into the through electrode 130 which vertically penetrates the substrate 100 and the first interlayer insulating layer 104, and the insulating layer 110a may be formed into the via insulating layer 110 which electrically insulates the through electrode 130 from the substrate 100. When the metal layer 120a is further formed, the metal layer 120a may be formed into the barrier layer 120 which prevents a constituent (e.g., Cu) of the through electrode 130 from diffusing into the substrate 100 and/or the integrated circuit 103. When the second polishing stop layer 192 is not removed as illustrated in FIG. 2F, the second polishing stop layer 192 may be planarized together with the conductive layer 130a and then removed.

In some embodiments, since the second polishing stop layer 192 covers the first polishing stop layer 191, the first polishing stop layer 191 may have thickness uniformity, as described with reference to FIGS. 2C and 2D, which protects the integrated circuit 103 from the polishing process. Besides, the first polishing stop layer 191 may prevent the constituent (e.g., Cu) of the through electrode 130 from moving into the integrated circuit 103. Selectively, an annealing process may be further performed after the polishing process, and thereafter a second polishing process may be further performed after the annealing process. Due to the annealing process, the through electrode 130 may expand to form a protrusion 130e which rises up over the first polishing stop layer 191. The protrusion 130e of the through electrode 130 may be removed when the second polishing process is performed.

Referring to FIG. 2H, the first polishing stop layer 191 may be removed by an etch-back process and the first interlayer insulating layer 104 is exposed. When the protrusion 130e of the through electrode 130 still remains, the protrusion 130e may be removed together with the first polishing stop layer 191 by the etch-back process.

Referring to FIG. 2I, a back-end process may be performed. For example, the single-layered or multi-layered metal line 152 may be formed on the first interlayer insulating layer 104 to be coupled to the through electrode 130. The bonding pad 154 may be formed to be coupled to the metal line 152, and a second interlayer insulating layer 106 may be formed to cover the metal line 152 and the bonding pad 154. The metal line 152 and the bonding pad 154 may be formed by depositing and patterning metal such as copper or aluminum. The second interlayer insulating layer 106 may be formed by depositing insulating material such as a silicon oxide layer or a silicon nitride layer identical or similar to the first interlayer insulating layer 104. The upper insulating layer 107 may be formed to open the bonding pad 154 by depositing and patterning a silicon oxide layer, a silicon nitride layer, or a polymer layer. Selectively, a bumping process may be further performed to form the upper terminal 160 such as solder ball or solder bump coupled to the bonding pad 154. The first and second interlayer insulating layers 104 and 106 may constitute the interlayer insulating layer 102 between the substrate 100 and the upper insulating layer 107.

Referring to FIG. 2J, the substrate 100 may be recessed to protrude the through electrode 130. For example, the first bottom surface 100b of the substrate 100 may be recessed using at least one of an etching process, a chemical mechanical polishing process, a grinding process, or any combination thereof with an etchant capable of selectively etching a constituent (e.g., silicon) of the substrate 100. This recess process may be performed to expose a third bottom surface 100d that is more adjacent to the top surface 100a compared to the first bottom surface 100b so that a lower portion 130p of the through electrode 130 may protrude over the third lower surface 100d. For example, a chemical mechanical polishing process may be performed on the first bottom surface 100b to expose a second bottom surface 100c through which the through electrode 130 is not revealed, and a dry etching process may be performed on the second bottom surface 100c to create the third bottom surface 100d. The process for protruding the through electrode 130 may be performed in a state that a carrier 70 is attached to the top surface 100a of the substrate 100 with an adhesive layer 72 interposed between the carrier 70 and the substrate 100. In the process for protruding the through electrode 130, the top surface 100a of the substrate 100 may face upward or downward. In the specification, the top surface 100a may be referred to as an active surface and the third bottom surface 100d may be referred to as an inactive surface.

Referring to FIG. 2K, the lower insulating layer 108 may be formed on the inactive surface 100d of the substrate 100. For example, a silicon oxide layer or a silicon nitride layer may be deposited on the inactive surface 100d to cover the through electrode 130, and the silicon oxide layer or the silicon nitride layer may be polished to form the lower insulating layer 108 exposing the through electrode 130. The lower terminal 107 may be formed on the lower insulating layer 107 to be coupled to the through electrode 130. A metal layer 172 may be further formed between the through electrode 130 and the lower terminal 107, and a plating layer 174 may be further formed on the lower terminal 170. As a result of the afore-described processes, the semiconductor device 1 of FIG. 1A may be configured to have an electrical interconnection 11 of via-middle structure.

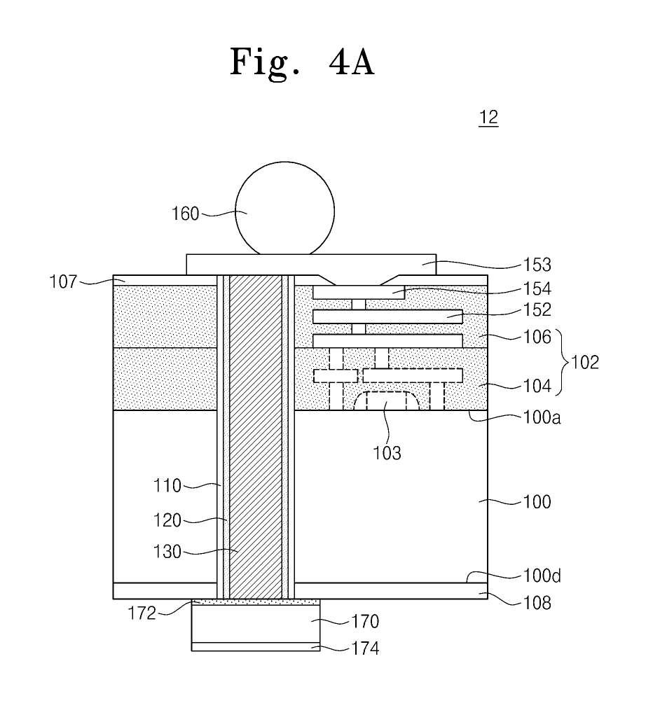

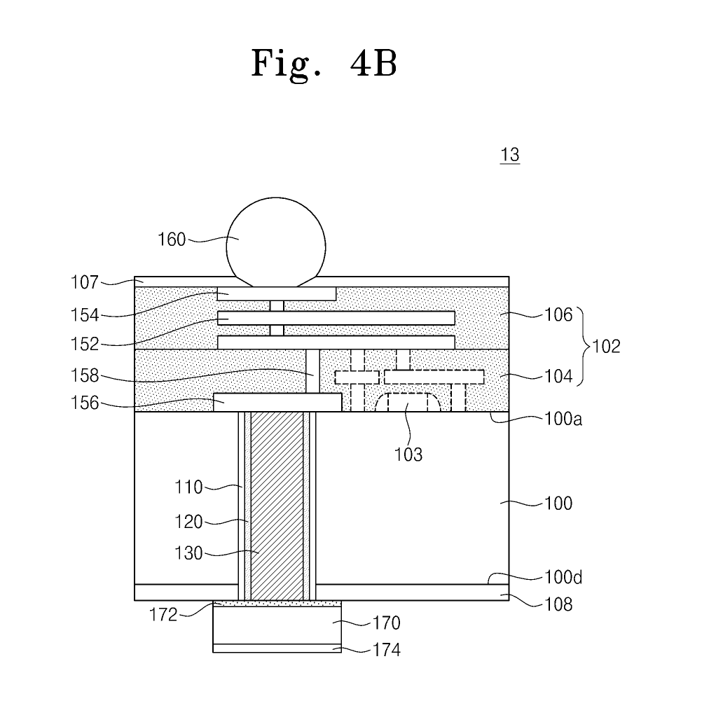

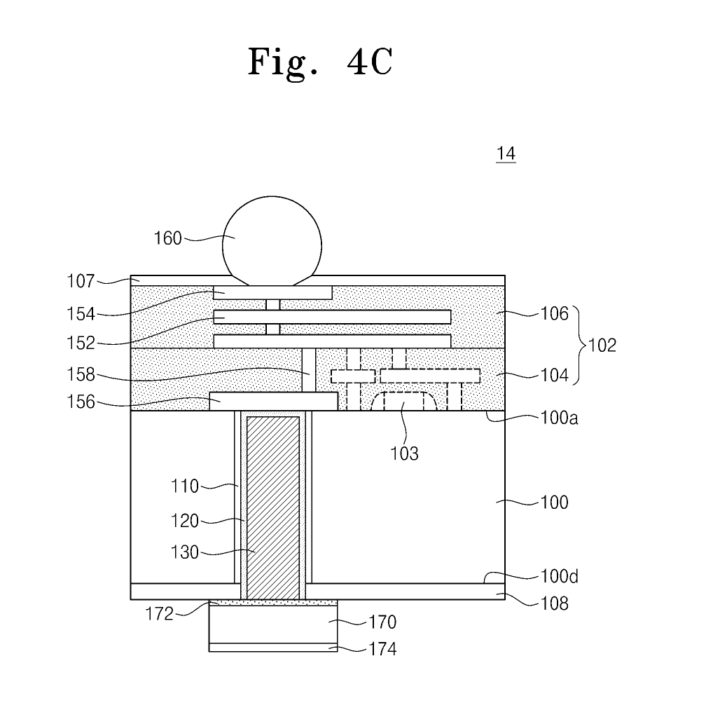

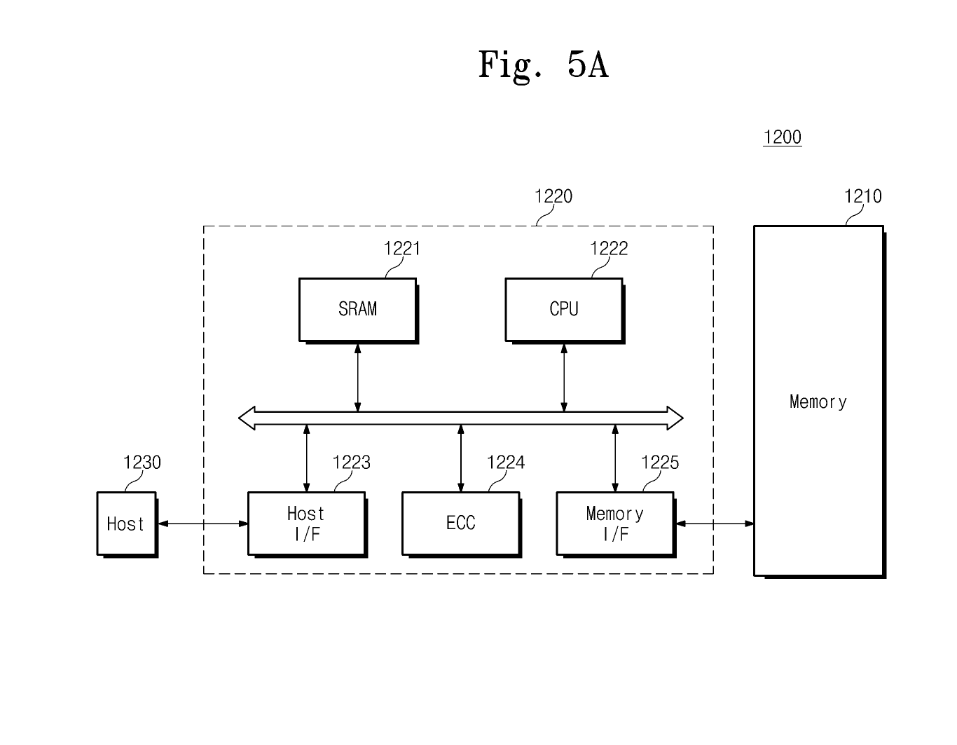

FIGS. 4A to 4C are cross sectional views illustrating modified embodiments of FIG. 2K.

Referring to FIG. 4A, an electrical interconnection 12 may have a via-last structure that the through electrode 130 is formed after the integrated circuit 103 and the metal line 152 are formed. The through electrode 130 may have a pillar shape that penetrates the interlayer insulating layer 102 and the substrate 100. An upper line 153 may be further provided on the upper insulating layer 107 to electrically connect the through electrode 130 to the bonding pad 154. The through electrode 130 may further penetrate the upper insulating layer 107 to be coupled to the upper line 153.

Referring to FIG. 4B, an electrical interconnection 13 may have a via-first structure that the through electrode 130 is formed before the integrated circuit 103 and the metal line 152 are formed. An interconnection line 156 may be further provided on the active surface 100a of the substrate 100 to be electrically connected to the through electrode 130 and electrically insulated from the substrate 100. The through electrode 130 may have a pillar shape penetrating the substrate 100 and is electrically connected to the metal line 152 and/or the integrated circuit 103 by an interconnection via 158 which electrically connects the interconnection line 156 to the metal line 152.

Referring to FIG. 4C, an electrical interconnection 14 may have a via-last structure that the through electrode 130 is formed after recessing of the substrate 100 having the integrated circuit 103 and the metal line 152 formed thereon. The barrier layer 120 may have a cup shape whose top portion contacting the interconnection line 156 is closed and whose bottom portion contacting the lower terminal 170 is open.

The through electrodes 130 as illustrated in FIGS. 4A to 4C may be formed using processes identical or similar to those as illustrated in FIGS. 2A to 2H.

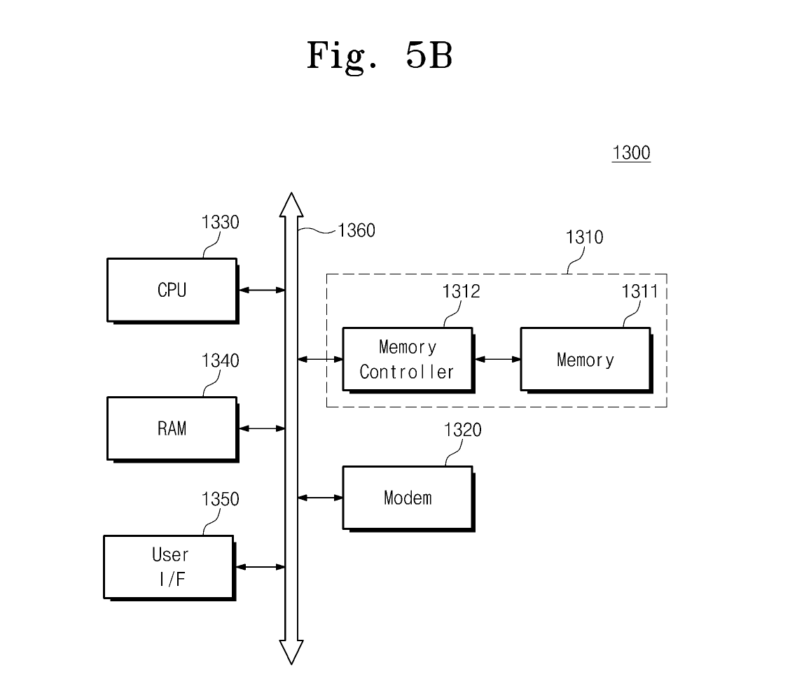

FIG. 5A is a schematic block diagram illustrating an example of memory cards including a semiconductor apparatus according to exemplary embodiments of the present inventive concepts.

Referring to FIG. 5A, a semiconductor memory 1210 including at least one of the semiconductor device 1 and the semiconductor package 90 according to exemplary embodiments of the inventive concepts is applicable to a memory card 1200. For example, the memory card 1200 may include a memory controller 1220 generally controlling data exchange between a host 1230 and the semiconductor memory 1210. An SRAM 1221 is used as a work memory of a processing unit 1222. A host interface 1223 has a data exchange protocol of a host connected to the memory card 1200. An error correction coding block 1224 detects and corrects errors of data that are read from the semiconductor memory 1210. A memory interface 1225 interfaces the semiconductor memory 1210 according to the example embodiments. The processing unit 1222 generally controls data exchange of the memory controller 1220.

FIG. 5B is a schematic block diagram illustrating an example of information process system including a semiconductor apparatus according to exemplary embodiments of the present inventive concepts.

Referring to FIG. 5B, an information processing system 1300 may include a memory system 1310 having at least one of the semiconductor device 1 and the semiconductor package 90 according exemplary embodiments of the inventive concepts. The information processing system 1300 may include a mobile device or a computer. For example, the information processing system 1300 may include a modem 1320, a central processing unit 1330, a RAM 1340, and a user interface 1350 electrically connected to the memory system 1310 via a system bus 1360. The memory 1310 may include a memory 1311 and a memory controller 1312 and have substantially the same configuration as that of the memory card 1200 in FIG. 5A. The memory system 1310 stores data processed by the central processing unit 1330 or data input from the outside. The information process system 1300 may be provided as a memory card, a solid state disk, a semiconductor device disk, a camera image sensor, and other application chipsets. In some embodiments, the memory system 1310 may be used as a portion of a solid state drive (SSD), and in this case, the information processing system 1300 may stably and reliably store a large amount of data in the memory system 1310.

According to embodiments of the present invention, the polishing stop layer is covered with the oxidation prevention layer such that oxidation of the polishing stop layer is prevented and a thickness thereof is secured. Due to the thickness uniformity of the polishing stop layer, the inferiority of the polishing process can be eliminated or reduced and yield can be improved. Moreover, an electrical failure of the integrated circuit can be suppressed and electrical characteristics can be improved.

Although the present invention has been described in connection with the embodiment of the present invention illustrated in the accompanying drawings, it is not limited thereto. It will be apparent to those skilled in the art that various substitution, modifications and changes may be thereto without departing from the scope and spirit of the invention.

What is claimed is:

1. A method for fabricating a semiconductor device, the method comprising:
forming a polishing stop layer having a multi-layered structure on a substrate;
forming a via hole partially penetrating the substrate;
providing the substrate with a first cleaning solution to first clean the substrate;
providing the substrate with a second cleaning solution to second clean the substrate, the second cleaning solution being different from the first cleaning solution; and
forming a through electrode in the via hole.

2. The method of claim 1, wherein forming the polishing stop layer comprises:
forming a first insulating layer on the substrate; and
forming a second insulating layer on the first insulating layer, the second insulating layer including an insulator different from that of the first insulating layer.

3. The method of claim 2, wherein the first insulating layer comprises a silicon nitride layer and the second insulating layer comprises a silicon oxide layer.

4. The method of claim 1, wherein forming the polishing stop layer comprises:
forming a first insulating layer on the substrate; and
forming a second insulating layer on the first insulating layer, the second insulating layer including an insulator identical to that of the first insulating layer,
wherein a component content of the second insulating layer is different from that of the first insulating layer.

5. The method of claim 4, wherein the first and second insulating layers comprise a silicon nitride layer, wherein the second insulating layer has hydrogen content lower than that of the first insulating layer.

6. The method of claim 1, wherein forming the via hole comprises:
forming an organic mask on the polishing stop layer; and
patterning the substrate using the organic mask to form the via hole whose top end is opened to a top surface of the substrate and whose bottom end is not reached a bottom surface of the substrate.

7. The method of claim 6, wherein the first cleaning solution comprises sulfuric acid and hydrogen peroxide.

8. The method of claim 7, wherein the second cleaning solution comprises hydrogen fluoride.

9. The method of claim 1, wherein forming the through electrode comprises:
forming a via insulating layer extending along an inner surface of the via hole;
forming a conductive layer filling the via hole on the substrate; and
polishing the conducive layer to form the through electrode that fills the via hole and is electrically insulated from the substrate by the via insulating layer.

10. The method of claim 9, after polishing the conductive layer, further comprising removing the polishing stop layer.

11. A method for fabricating a semiconductor device, the method comprising:
forming a polishing stop layer on a substrate;
forming an oxidation preventing layer covering the polishing stop layer;
forming a via hole partially penetrating the substrate;
providing the substrate with a first cleaning solution including sulfuric acid and hydrogen peroxide to first clean the substrate;
providing the substrate with a second cleaning solution including hydrogen fluoride to second clean the substrate;
forming a via insulating layer extending along an inner surface of the via hole;
forming a conductive layer filling the via hole on the substrate;
polishing the conductive layer until the polishing stop layer is exposed so as to form a through electrode; and
removing the polishing stop layer,
wherein the oxidation preventing layer prevents the polishing layer from contacting the first cleaning solution such that the polishing stop layer is prevented from oxidizing.

12. The method of claim 11, wherein the polishing stop layer comprises a silicon nitride layer and the oxidation preventing layer comprises a silicon oxide layer.

13. The method of claim 11, wherein forming the via hole comprises:
coating and patterning a photoresist on the oxidation preventing layer to form a mask; and
performing an etching using the mask to remove a portion of the substrate,
wherein the via hole is opened to a top surface of the substrate and not reached a bottom surface of the substrate.

14. The method of claim 13, after forming the via hole, further comprising removing the mask,
wherein first clean the substrate comprises removing a remainder of the mask.

15. The method of claim 13, wherein second clean the substrate comprises removing the oxidation preventing layer.
